(19) United States
(12) Patent Application Publication
(10) Pub. No.: US 2025/0226289 A1
(43) Pub. Date: Jul. 10, 2025

(54) COOLING DEVICE

(71) Applicant: MITSUBISHI HEAVY INDUSTRIES, LTD., Tokyo (JP)

(72) Inventors: Tsutomu Kawamizu, Tokyo (JP); Hiroki Matsuda, Tokyo (JP)

(73) Assignee: MITSUBISHI HEAVY INDUSTRIES, LTD., Tokyo (JP)

(21) Appl. No.: 18/847,926

(22) PCT Filed: Oct. 28, 2022
(86) PCT No.: PCT/JP2022/040415

§ 371 Date: Sep. 17, 2024

(30) Foreign Application Priority Data
Mar. 22, 2022 (JP) 2022-045924

(51) Int. Cl. H01L 23/473; H05K 7/20

(52) U.S. Cl. CPC H01L 23/473; H05K 7/20927

(57) ABSTRACT

A cooling device of the present disclosure is a cooling device that cools a plurality of semiconductor components, which are mounted on a front surface of a substrate and are arranged in a first direction, the cooling device including a base attached to a rear surface of the substrate, a bottom plate disposed apart from the base to form a flow path through which a refrigerant flows between the bottom plate and the base, and a cooling body disposed in the flow path, in which the flow path is provided independently for each of the semiconductor components to have a plurality of flow path sections which extend in a second direction orthogonal to the first direction, and an introduction port configured to supply the refrigerant to each of the flow path sections is formed in a central portion of the bottom plate in the second direction.

### TECHNICAL FIELD

The present disclosure relates to a cooling device.

Priority is claimed on Japanese Patent Application No. 2022-045924, filed Mar. 22, 2022, the content of which is incorporated herein by reference.

### BACKGROUND ART

As a device for cooling a semiconductor component (chip), for example, a device disclosed in Patent Document 1 is known. In the device disclosed in Patent Document 1, a cooling water passage through which cooling water flows is formed between a plurality of semiconductor modules. It is considered that the cooling water is guided from one end of the cooling water passage in the lateral direction and the semiconductor modules can be sequentially cooled.

### CITATION LIST

### Patent Document

Patent Document 1: Japanese Unexamined Patent Publication No. 2006-203138

### SUMMARY OF INVENTION

### Technical Problem

Meanwhile, in a case where the plurality of semiconductor components are mounted as described above, the heat generation of each semiconductor component is superimposed, so that a temperature in a central portion of the plurality of semiconductor components is likely to be high. In addition, as in Patent Document 1, in a configuration in which the cooling water is allowed to flow sequentially in the lateral direction from one end of a cooling water passage, the refrigerant having a high temperature is sequentially supplied to cool the other semiconductor components, so that the cooling effect is reduced as the semiconductor component is located on the downstream side in the flow direction of the refrigerant.

The present disclosure has been made in order to solve the above-described problems, and an object of the present disclosure is to provide a cooling device that exhibits a higher cooling effect.

### Solution to Problem

In order to solve the above problems, according to the present disclosure, there is provided a cooling device that cools a plurality of semiconductor components, which are mounted on a front surface of a substrate and are arranged in a first direction, the cooling device including a base attached to a rear surface of the substrate; a bottom plate disposed apart from the base to form a flow path through which a refrigerant flows between the bottom plate and the base; and a cooling body disposed in the flow path, in which the flow path is provided independently for each of the semiconductor components to have a plurality of flow path sections which extend in a second direction orthogonal to the first direction, and an introduction port configured to supply the refrigerant to each of the flow path sections is formed in a central portion of the bottom plate in the second direction.

### Advantageous Effects of Invention

According to the present disclosure, it is possible to provide a cooling device that exhibits a higher cooling effect.

### BRIEF DESCRIPTION OF DRAWINGS

FIG. 1 is a cross-sectional view showing the configuration of a cooling device and a substrate according to a first embodiment of the present disclosure.

FIG. 2 is a plan view showing the configuration of a bottom plate of the cooling device according to the first embodiment of the present disclosure.

FIG. 3 is a cross-sectional view showing the configuration of a cooling device and a substrate according to a second embodiment of the present disclosure.

FIG. 4 is a plan view showing the configuration of a bottom plate of the cooling device according to the second embodiment of the present disclosure.

FIG. 5 is a plan view showing a modification example of the cooling device according to the second embodiment of the present disclosure.

FIG. 6 is a plan view showing the configuration of a bottom plate of a cooling device according to a third embodiment of the present disclosure.

FIG. 7 is a plan view showing a modification example of the cooling device according to the third embodiment of the present disclosure.

### DESCRIPTION OF EMBODIMENTS

### First Embodiment

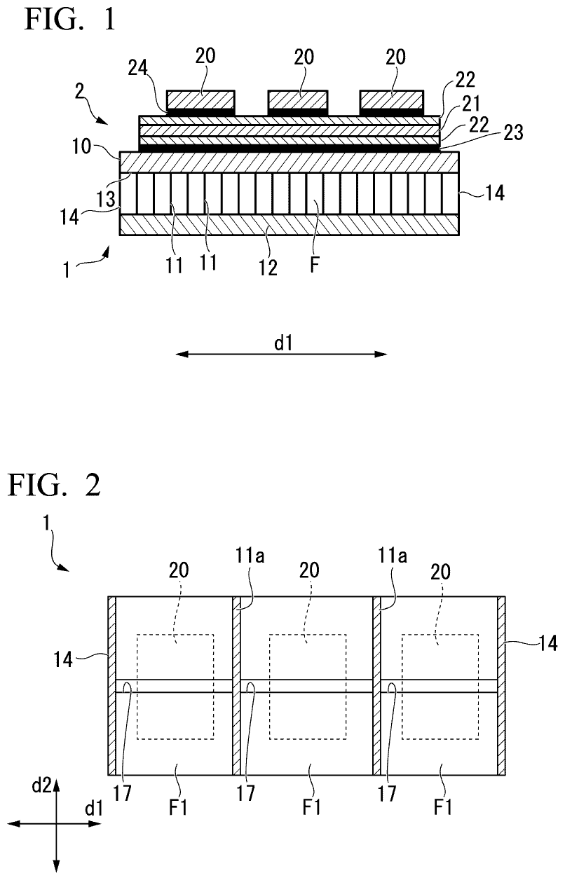

Hereinafter, a substrate 2 and a cooling device 1 according to a first embodiment of the present disclosure will be described with reference to FIG. 1 and FIG. 2. The cooling device 1 is for cooling semiconductor components 20 mounted on the substrate 2 with a liquid refrigerant.

### (Configuration of Substrate)

As shown in FIG. 1, the substrate 2 includes a substrate main body 21, copper patterns 22, and bonding materials 23 and 24.

The substrate main body 21 is formed in a plate shape of, for example, a glass epoxy resin, a bakelite resin, or the like. The copper pattern 22 is vapor-deposited on each of a front surface and a rear surface of the substrate main body 21. A desired printed wiring line is formed on the copper patterns 22 by etching. The bonding material 24 is provided to fix the semiconductor components 20 to the copper pattern 22.

A plurality (three in this example) of the semiconductor components 20 are disposed on the substrate 2. The semiconductor components 20 are electrically connected to the above-described copper patterns 22. The semiconductor components 20 are, for example, a power transistor or a power FET, and generate heat due to an internal resistance accompanying an operation thereof. The semiconductor components 20 are disposed on the substrate 2 at intervals from each other in a first direction d1.

### (Configuration of Cooling Device)

Next, a configuration of the cooling device 1 will be described. As shown in FIG. 1, the cooling device 1 includes a base 10, fins 11, and a bottom plate 12. The base 10, the fins 11, and the bottom plate 12 are formed of a metal material having good thermal conductivity such as aluminum or copper. The cooling device 1 can also be formed by an Additive Manufacturing (AM) method. In addition, the base 10, the fins 11, and the bottom plate 12 may be integrally formed, or only the bottom plate 12 may be attachable to and detachable from the base 10 and the fins 11. In this case, it is desirable that a leakage prevention member such as an O-ring is disposed on a bonding surface between the bottom plate 12 and the fin 11.

The base 10 is fixed to a rear surface (that is, a surface facing a side opposite to the front surface on which the semiconductor components 20 are mounted) of the above-described substrate 2 by the bonding material 23. The base 10 has a plate shape having a larger area than the substrate 2.

A plurality of fins 11 (cooling bodies) are provided on a rear surface 13 of the base 10. Each of the fins 11 protrudes in a direction apart from the base 10. More specifically, as shown in FIG. 2, the fins 11 extend in a second direction d2, which is a horizontal direction orthogonal to the first direction d1, along the rear surface 13 of the base 10, and are arranged at intervals in the first direction d1. As a result, a flow path F through which a refrigerant flows is formed between the fins 11. In addition, a pair of side walls 14 are provided on both sides in the second direction d2.

The flow path F is partitioned into three flow path sections F1 independently for each of the above-described three semiconductor components 20. Specifically, the flow path sections F1 adjacent to each other are partitioned by one fin 11a among the plurality of fins 11. The fin 11a has the same shape and the same length as the other fins 11. In addition, in FIG. 2, only the fin 11a is shown for the simplicity of illustration.

Again, as shown in FIG. 1, the above-described fins 11 are supported between the base 10 and the bottom plate 12. The bottom plate 12 has a plate shape disposed at intervals from the base 10 by the amount of the flow path F. The bottom plate 12 extends in the first direction d1 and the second direction d2. The thickness of the bottom plate 12 is constant over the entire region.

An introduction port 17 for guiding the refrigerant from the outside into the flow path F is formed at the central portion of the bottom plate 12 in the second direction d2 (that is, right below the central portion of each semiconductor component 20 in the second direction d2). The introduction port 17 is a rectangular opening extending in the first direction d1 (see FIG. 2). The length of the introduction port 17 in the second direction d2 is constant through all the flow path sections F1. The refrigerant is introduced in a direction toward the base 10 from the bottom plate 12 through the introduction port 17. The refrigerant flows through the space between the respective fins 11 toward both sides in the second direction d2. In addition, alcohol or the like is suitably used as the refrigerant in addition to low-temperature water.

### (Operation and Effect)

In a case where a current flows through the above-described semiconductor components 20, the semiconductor components 20 generate heat in association with internal resistance. Here, in the related art, a configuration in which the plurality of semiconductor components 20 are sequentially cooled from the upstream side to the downstream side by supplying the refrigerant to the plurality of semiconductor components 20 in one direction (for example, the first direction d1) has been generally adopted. However, in this configuration, there is a problem in that a cooling effect on the semiconductor components 20 on the downstream side is reduced because the refrigerant at a high temperature is supplied to the semiconductor components 20 located on the downstream side. Therefore, the present embodiment adopts the above-described configuration.

With the above-described configuration, each semiconductor component 20 can be individually cooled by the refrigerant flowing through each flow path section F1. That is, a new refrigerant is normally supplied to each of the semiconductor components 20. As a result, the refrigerant is less likely to be received by the influence of heat between the semiconductor components 20, and thus the cooling effect can be improved. In addition, since the introduction port 17 is formed at the central portion of the flow path section F1 in the second direction d2, the low-temperature refrigerant at an initial stage can be actively supplied to the semiconductor components. As a result, it is possible to more efficiently and positively cool the semiconductor components 20.

Further, with the above-described configuration, the fins 11 extend in the second direction d2, so that it is possible to restrict the refrigerant flow direction only to the second direction d2. As a result, for example, the possibility that the refrigerant is retained or a vortex is formed in the flow path F is reduced. As a result, the refrigerant flows more smoothly, so that it is possible to more efficiently cool the semiconductor components 20. In addition, it is possible to form a plurality of flow path sections F1 only by providing the plurality of fins 11. That is, it is possible to form the flow path section F1 without requiring other members. As a result, it is possible to realize a reduction in manufacturing costs and maintenance costs.

The first embodiment of the present disclosure has been described above. In addition, various changes or modifications can be made to the above configuration without departing from the scope of the present disclosure. For example, the number of the semiconductor components 20 is not limited to three, and may be four or more. Also in this case, it is possible to obtain the same operation and effect as described above by forming the number of flow path sections F1 corresponding to the number of the semiconductor components 20.

### Second Embodiment

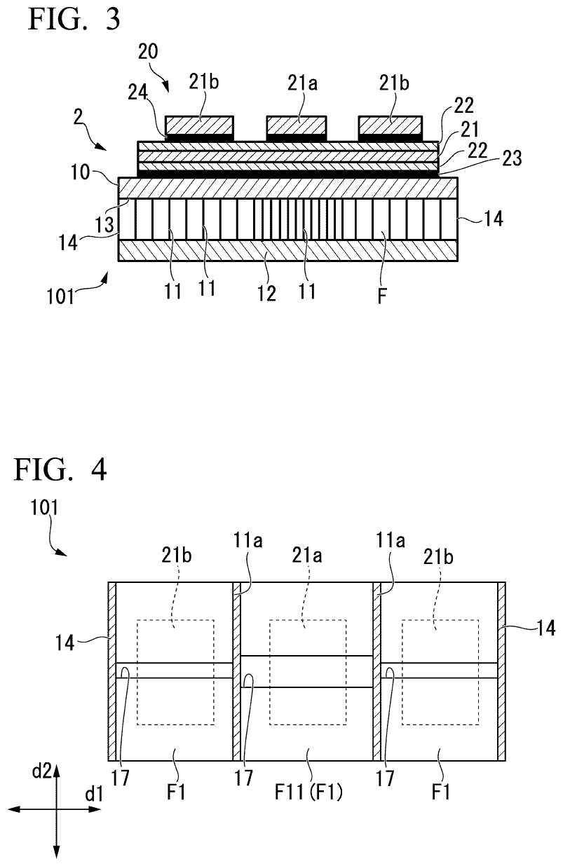

Hereinafter, a second embodiment of the present disclosure will be described with reference to FIGS. 3 and 4. In addition, the same configurations as in the first embodiment described above are denoted by the same reference signs, and detailed descriptions thereof will be omitted. In the following description, among the three semiconductor components 20, the semiconductor component 20 located at the central portion of the first direction d1 is referred to as a first semiconductor component 21a, and the remaining two semiconductor components 20 are referred to as second semiconductor components 21b.

As shown in FIG. 3, in the cooling device 101 according to the present embodiment, the interval between the fins 11 in the flow path section F1 (first flow path section F11) corresponding to the first semiconductor component 21a (that is, the interval between the fins 11 in the first direction d1) is smaller than the interval between the fins 11 in the other flow path sections F1. In other words, in the first flow path section F11 located at the central portion, the fins 11 are arranged more densely compared to the other flow path sections F1.

Further, as shown in FIG. 4, in the first flow path section F11, the length of the introduction port 17 in the second direction d2 is larger than the length of the introduction port 17 of the other flow path sections F1. As a result, the flow rate flowing into the first flow path section F11 is equal to or more than the flow rate of the other flow path sections F1.

### (Operation and Effect)

Here, in a case in which it is assumed that the heat generation amounts of the plurality of semiconductor components 20 are equal to each other, in the periphery of the first semiconductor component 21a disposed in the central portion among the above-described three semiconductor components 20, the heat generation is superimposed by receiving the influence of the second semiconductor component 21b. As a result, the first semiconductor component 21a is more likely to be at a high temperature compared to the second semiconductor component 21b. Therefore, in the present embodiment, the above-described configuration is adopted.

With the above-described configuration, in the first flow path section F11 corresponding to the semiconductor component 20 (first semiconductor component 21a) in the central portion, the interval between the fins 11 is narrow and the length in the second direction d2 of the introduction port 17 is larger than the length of the other flow path sections F1. As a result, it is possible to increase the cooling effect by the fins 11 that are more densely disposed while supplying the same amount or more of the refrigerant to the first semiconductor component 21a in the central portion that is likely to generate heat as the other flow path sections F1. Therefore, it is possible to suppress the influence of the superimposed heat generation around the first semiconductor component 21a to be small, and it is possible to significantly reduce the possibility that each semiconductor component 20 thermally runs away or is damaged.

The second embodiment of the present disclosure has been described above. In addition, various changes or modifications can be made to the above configuration without departing from the scope of the present disclosure.

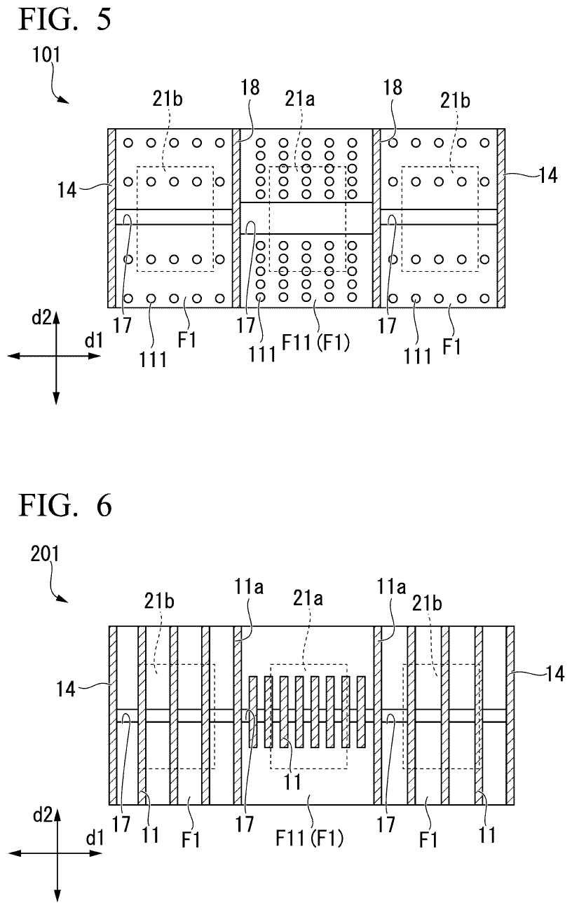

For example, as shown as a modification example in FIG. 5, pins 111 can also be applied as the cooling body instead of the fins 11. In this case, as shown in the same drawing, the first flow path section F11 is disposed so that the interval between the pins 111 is narrow compared to other flow path sections F1. In addition, each flow path section F1 is partitioned from each other by the partition wall portion 18 which has a plate shape extending in the second direction d2.

With the above configuration, since the pins 111 are used as the cooling body, a surface area of a surface in contact with the refrigerant is increased as compared to the fins 11. As a result, the heat transferred from the pin 111 to the refrigerant is increased. As a result, it is possible to further improve the cooling performance of the cooling device 101 in addition to the operation and effect described in the second embodiment.

### Third Embodiment

Next, a third embodiment of the present disclosure will be described with reference to FIG. 6. In addition, the same components as those in each embodiment are denoted by the same reference numerals, and a detailed description thereof will be omitted. As shown in the drawing, in the cooling device 201 according to the present embodiment, the length of the introduction port 17 in the second direction d2 is constant through all the flow path sections F1.

Further, in the first flow path section F11 corresponding to the first semiconductor component 21a, the length of the fins 11 in the second direction d2 is small as compared to the fins 11 of the other flow path sections F1. Specifically, in the fin 11 of the first flow path section F11, both end parts are close to the central side in the second direction d2, so that the total length thereof is shortened. Further, in the first flow path section F11, the interval between the fins 11 in the first direction d1 is smaller than the interval between the fins 11 in the other flow path sections F1.

### (Operation and Effect)

With the above configuration, the lengths of the introduction ports 17 are the same in the respective flow path sections F1, and the intervals between the fins 11 are narrow in the first flow path section F11 corresponding to the first semiconductor component 21a in the central portion. Therefore, in the first flow path section F11, the pressure loss with respect to the refrigerant tends to be large as compared to the other flow path sections F1.

Therefore, in the first flow path section F11, the length of the fins 11 in the second direction d2 is set to be short as compared to the length of the fins 11 in the other flow path sections F1. As a result, a section in which the pressure loss occurs in a case of flowing between the fins 11 is shortened in the first flow path section F11. As a result, it is possible to make the flow rate of the refrigerant supplied to the first flow path section F11 equal to or more than the flow rate of the other flow path sections F1. In the first flow path section F11 corresponding to the semiconductor component 20 (first semiconductor component 21a) in the central portion, the fins 11 are disposed with a narrow interval between each other, so that the cooling effect is increased, and the refrigerant equal to or more than those in the other flow path sections F1 is supplied by shortening the length. As a result, it is possible to suppress the influence of the superimposed heat generation around the first semiconductor component 21a to be small, and it is possible to significantly reduce the possibility that each semiconductor component 20 thermally runs away or is damaged.

Further, since the lengths of the introduction ports 17 in the second direction d2 are constant between the respective flow path sections F1, it is also possible to reduce a processing cost and a processing time in a case of forming the introduction port 17. As a result, it is possible to reduce the manufacturing costs of the cooling device 201.

The third embodiment of the present disclosure has been described above. In addition, various changes or modifications can be made to the above configuration without departing from the scope of the present disclosure.

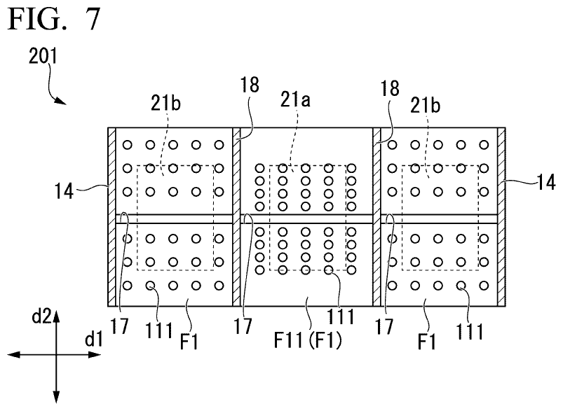

For example, as shown as a modification example in FIG. 7, it is possible to use the pin 111 as the cooling body instead of the fin 11. In this case, in the first flow path section F11, the interval between the pins 111 is set to be smaller than the interval between the pins 111 in the other flow path sections F1. In addition, in the first flow path section F11, the length of a region in which the pins 111 are disposed in the second direction d2 is set to be smaller than the length of the region in which the pins 111 are disposed in the other flow path sections F1.

With the above configuration, since the pins 111 are used as the cooling body, a surface area of a surface in contact with the refrigerant is increased as compared to the fins 11. As a result, the heat transferred from the pin 111 to the refrigerant is increased. As a result, it is possible to further improve the cooling performance of the cooling device 201 in addition to the operation and effect described in the third embodiment.

### <Appendix>

The cooling device 1, 101, or 201 described in each embodiment is grasped, for example, as follows.

(1) A cooling device 1, 101, or 201 according to a first aspect is a cooling device 1, 101, or 201 that cools a plurality of semiconductor components 20, which are mounted on a front surface of a substrate 2 and are arranged in a first direction d1, the cooling device 1, 101, or 201 includes: a base 10 attached to a rear surface of the substrate 2, a bottom plate 12 disposed apart from the base 10 to form a flow path F through which a refrigerant flows between the bottom plate 12 and the base 10, and a cooling body disposed in the flow path F, in which the flow path F is provided independently for each of the semiconductor components 20 to have a plurality of flow path sections F1 which extend in a second direction d2 orthogonal to the first direction d1, and an introduction port 17 configured to supply the refrigerant to each of the flow path sections F1 is formed in a central portion of the bottom plate 12 in the second direction d2.

With the above-described configuration, each semiconductor component 20 can be individually cooled by the refrigerant flowing through each flow path section F1. In addition, since the introduction port 17 is formed at the central portion of the flow path section F1, the low-temperature refrigerant at an initial stage can be actively supplied to the semiconductor components 20. As a result, it is possible to efficiently and positively cool the semiconductor components 20.

(2) A cooling device 1, 101, or 201 according to a second aspect is the cooling device 1, 101, or 201 of (1), in which the cooling body may be a plurality of fins 11 that protrude from the base 10 toward the bottom plate 12 and extend in the second direction d2, and a pair of the flow path sections F1 adjacent to each other may be partitioned by one fin 11a.

With the above-described configuration, it is possible to restrict the refrigerant flow direction only to the second direction d2 by extending the fins 11 in the second direction d2. Therefore, the refrigerant flows more smoothly, so that it is possible to more efficiently cool the semiconductor components 20.

(3) A cooling device 101 according to a third aspect is the cooling device 101 of (2), in which, in the flow path section F1 corresponding to the semiconductor component 20 located in a central portion in the first direction d1 among the plurality of semiconductor components 20, an interval between the fins 11 may be narrow as compared to the other flow path sections F1, and a length of the introduction port 17 in the second direction d2 may be large as compared to the other flow path sections F1.

With the above-described configuration, in the flow path section F11 corresponding to the semiconductor component 20 in the central portion, the interval between the fins 11 is narrow, and the length of the introduction port 17 is large. As a result, it is possible to make the flow rate of the refrigerant supplied to the semiconductor component 20 in the central portion, which is likely to receive the superimposed influence of the heat generation, equal to or more than that of the other flow path section F1, and it is possible to further increase the cooling effect by the pins 11 which are more closely disposed.

(4) A cooling device 201 according to a fourth aspect is the cooling device 201 of (2), in which a length of the introduction port 17 in the second direction d2 may be the same between the plurality of flow path sections F1, and, in the flow path section F11 corresponding to the semiconductor component 20 located in a central portion in the first direction d1 among the plurality of semiconductor components 20, an interval between the fins 11 may be narrow as compared to the other flow path sections F1, and the lengths of the fins 11 in the second direction d2 may be small as compared to the lengths of the fins 11 in the other flow path sections F1.

With the above configuration, the lengths of the introduction port 17 are the same in the respective flow path sections F1, and the intervals between the fins 11 are narrow in the flow path section F11 corresponding to the semiconductor component 20 in the central portion. On the other hand, in the flow path section F1 corresponding to the semiconductor component 20 in the central portion, the length of the fins 11 in the second direction d2 is short. As a result, it is possible to make the flow rate of the refrigerant supplied to the flow path section F11 corresponding to the semiconductor component 20 in the central portion equal to or more than the flow rate of the refrigerant supplied to the other flow path sections F1.

(5) A cooling device 101 or 201 according to a fifth aspect is the cooling device 101 or 201 of (1), in which the cooling body may be a plurality of pins 111 each having a rod shape extending from the base 10 toward the bottom plate 12, and the cooling device may further include a partition wall portion 18 provided between a pair of the flow path sections F1 adjacent to each other.

With the above configuration, since the pins 111 are used as the cooling body, the surface area is increased as compared to the fins 11. As a result, it is possible to further improve the cooling performance of the cooling device 1.

(6) A cooling device 101 according to a sixth aspect is the cooling device 101 of (5), in which, in the flow path section F11 corresponding to the semiconductor component 20 located in a central portion in the first direction d1 among the plurality of semiconductor components 20, an interval between the pins 111 may be narrow as compared to the other flow path sections F11, and a length of the introduction port 17 in the second direction d2 may be large as compared to the other flow path sections F1.

With the above-described configuration, in the flow path section F11 corresponding to the semiconductor component 20 in the central portion, the interval between the pins 111 is narrow, and the length of the introduction port 17 is large. As a result, it is possible to make the flow rate of the refrigerant supplied to the semiconductor component 20 in the central portion which is likely to generate heat equal to or more than that of the other flow path section F1, and it is possible to further increase the cooling effect by the pins 111 which are more closely disposed.

(7) A cooling device 201 according to a seventh aspect is the cooling device 201 of (5), in which the length of the introduction port 17 in the second direction d2 is the same between the plurality of flow path sections F1, and, in the flow path section F11 corresponding to the semiconductor component 20 located in a central portion in the first direction d1 among the plurality of semiconductor components 20, an interval between the pins 111 is narrow as compared to the other flow path sections F1, and a length of a region in which the pins 111 are disposed in the second direction d2 may be small as compared to lengths of regions in which the pins 111 are disposed in the other flow path sections F1.

With the above configuration, the length of the introduction port 17 is the same in each of the flow path sections F1, and the interval between the pins 111 is narrow in the flow path section F11 corresponding to the semiconductor component 20 in the central portion. On the other hand, in the flow path section F11 corresponding to the semiconductor component 20 in the central portion, the length of the region in which the pins 111 are disposed in the second direction d2 is small. As a result, it is possible to make the flow rate of the refrigerant supplied to the flow path section F1 corresponding to the semiconductor component 20 in the central portion equal to or more than the flow rate of the refrigerant supplied to the other flow path sections F1.

### Industrial Applicability

It is possible to provide a cooling device that exhibits a higher cooling effect.

### REFERENCE SIGNS LIST

1: Cooling device
2: Substrate
10: Base
11, 11a: Fin
12: Bottom plate
13: Rear surface
14: Side wall
17: Introduction port
18: Partition wall portion
20: Semiconductor component
21a: First semiconductor component
21b: Second semiconductor component
21: Substrate main body
22: Copper pattern
23: Bonding material
24: Bonding material
101: Cooling device
111: Pin
201: Cooling device
d1: First direction
d2: Second direction
F: Flow path
F1: Flow path section
F11: First flow path section

1-7. (canceled)

8. A cooling device that cools a plurality of semiconductor components, which are mounted on a front surface of a substrate and are arranged in a first direction, the cooling device comprising:
a base attached to a rear surface of the substrate;
a bottom plate disposed apart from the base to form a flow path through which a refrigerant flows between the bottom plate and the base; and
a cooling body disposed in the flow path, wherein
the flow path is provided independently for each of the semiconductor components to have a plurality of flow path sections which extend in a second direction orthogonal to the first direction,
an introduction port configured to supply the refrigerant to each of the flow path sections is formed in a central portion of the bottom plate in the second direction,
the cooling body is a plurality of fins that protrude from the base toward the bottom plate and extend in the second direction, and a pair of the flow path sections adjacent to each other are partitioned by one fin, and
in the flow path section corresponding to the semiconductor component located in a central portion in the first direction among the plurality of semiconductor components, an interval between the fins is narrow as compared to the other flow path sections, and a length of the introduction port in the second direction is large as compared to the other flow path sections.

9. A cooling device that cools a plurality of semiconductor components, which are mounted on a front surface of a substrate and are arranged in a first direction, the cooling device comprising:
a base attached to a rear surface of the substrate;
a bottom plate disposed apart from the base to form a flow path through which a refrigerant flows between the bottom plate and the base; and
a cooling body disposed in the flow path, wherein
the flow path is provided independently for each of the semiconductor components to have a plurality of flow path sections which extend in a second direction orthogonal to the first direction,
an introduction port configured to supply the refrigerant to each of the flow path sections is formed in a central portion of the bottom plate in the second direction,
the cooling body is a plurality of fins that protrude from the base toward the bottom plate and extend in the second direction, and a pair of the flow path sections adjacent to each other are partitioned by one fin,
a length of the introduction port in the second direction is the same between the plurality of flow path sections, and
in the flow path section corresponding to the semiconductor component located in a central portion in the first direction among the plurality of semiconductor components, an interval between the fins is narrow as compared to the other flow path sections, and lengths of the fins in the second direction are short as compared to the lengths of the fins in the other flow path sections.

10. A cooling device that cools a plurality of semiconductor components, which are mounted on a front surface of a substrate and are arranged in a first direction, the cooling device comprising:
a base attached to a rear surface of the substrate;
a bottom plate disposed apart from the base to form a flow path through which a refrigerant flows between the bottom plate and the base; and
a cooling body disposed in the flow path, wherein
the flow path is provided independently for each of the semiconductor components to have a plurality of flow path sections which extend in a second direction orthogonal to the first direction,
an introduction port configured to supply the refrigerant to each of the flow path sections is formed in a central portion of the bottom plate in the second direction,
the cooling body is a plurality of pins each having a rod shape extending from the base toward the bottom plate, and
the cooling device further includes a partition wall portion provided between a pair of the flow path sections adjacent to each other, and
in the flow path section corresponding to the semiconductor component located in a central portion in the first direction among the plurality of semiconductor components, an interval between the pins is narrow as compared to the other flow path sections, and a length of the introduction port in the second direction is large as compared to the other flow path sections.

11. A cooling device that cools a plurality of semiconductor components, which are mounted on a front surface of a substrate and are arranged in a first direction, the cooling device comprising:
a base attached to a rear surface of the substrate;
a bottom plate disposed apart from the base to form a flow path through which a refrigerant flows between the bottom plate and the base; and
a cooling body disposed in the flow path, wherein
the flow path is provided independently for each of the semiconductor components to have a plurality of flow path sections which extend in a second direction orthogonal to the first direction,
an introduction port configured to supply the refrigerant to each of the flow path sections is formed in a central portion of the bottom plate in the second direction,
the cooling body is a plurality of pins each having a rod shape extending from the base toward the bottom plate, and
the cooling device further includes a partition wall portion provided between a pair of the flow path sections adjacent to each other, and
a length of the introduction port in the second direction is the same between the plurality of flow path sections, and
in the flow path section corresponding to the semiconductor component located in a central portion in the first direction among the plurality of semiconductor components, an interval between the pins is narrow as compared to the other flow path sections, and a length of a region in which the pins are disposed in the second direction is short as compared to lengths of regions in which the pins are disposed in the other flow path sections.
